(19) United States
(12) Patent Application Publication
(10) Pub. No.: US 2009/0026463 A1
(43) Pub. Date: Jan. 29, 2009

(54) ARRAY SUBSTRATE FOR A DISPLAY DEVICE AND METHOD OF MANUFACTURING THE SAME

(75) Inventors: Jin-Hee Kang, Dong-gu, (KR); Chun-Gi You, Hwaseong-si (KR); Seong-Kweon Heo, Suwon-si (KR)

Correspondence Address: CANTOR COLBURN, LLP, 20 Church Street, 22nd Floor, Hartford, CT, 06103, US

(73) Assignee: SAMSUNG ELECTRONICS CO., LTD., Suwon-si (KR)

(21) Appl. No.: 12/173,476

(22) Filed: Jul. 15, 2008

(30) Foreign Application Priority Data
Jul. 25, 2007 (KR) 10-2007-0074670

(51) Int. Cl. H01L 33/00; H01L 21/20

(52) U.S. Cl. 257/72; 438/34; 257/E33.053; 257/E21.133

(57) ABSTRACT

An array substrate includes a thin-film transistor (TFT), a first insulation layer and a second insulation layer. The TFT is formed on the substrate. The TFT includes an active pattern, a gate metal pattern and a data metal pattern. The first insulation layer insulates the active pattern from the gate metal pattern. The second insulation layer is formed spaced apart by a predetermined width from at least one edge of the substrate. The second insulation layer insulates the gate metal pattern from the data metal pattern. Therefore, the second insulation layer is formed so that stress that is inflicted on a substrate may be decreased, thereby preventing deformation during a manufacturing process of the substrate.

This application claims priority to Korean Patent Application No. 2007-74670, filed on Jul. 25, 2007, and all the benefits accruing therefrom under 35 U.S.C. §119, the contents of which in its entirety are herein incorporated by reference.

### BACKGROUND OF THE INVENTION

1. Field of the Invention

The present invention relates to an array substrate and a method of manufacturing the array substrate. More particularly, the present invention relates to an array substrate for a liquid crystal display (“LCD”) device and a method of manufacturing the array substrate.

2. Description of the Related Art

Generally, a liquid crystal display (“LCD”) device includes an LCD panel displaying an image using light and a backlight assembly providing the LCD panel with the light. The LCD panel includes an array substrate having a plurality of thin-film transistors (“TFTs”) and a plurality of pixel electrodes formed thereon, a color filter substrate having a plurality of color filters and a liquid crystal layer interposed between the array substrate and the color filter substrate. Each of the plurality of TFTs include a gate electrode, a source electrode, a drain electrode and an active layer.

Amorphous silicon is a common component in the active layer; however, recently, polysilicon, which has excellent electrical conductivity, has been used in the active layer. When the active layer includes polysilicon a complete driving circuit of a plurality of TFTs may be formed in the array substrate. Here, the driving circuit may include an n-type metal-oxide semiconductor (“NMOS”) circuit using an n-type TFT, a p-type metal-oxide semiconductor (“PMOS”) circuit using a p-type TFT or a complementary metal-oxide semiconductor (“CMOS”) circuit using the n-type TFT and the p-type TFT.

A storage electrode is formed on the array substrate, which is overlapped with a portion of the pixel electrode to define a storage capacitor. Here, a high-density ion-doped silicon layer doped with ions of a Group 15 element at a high density is formed below the storage electrode. The high-density ion-doped silicon layer is spaced apart from the storage electrode by a predetermined distance to form a static capacitor.

The active layer, a plurality of metal layers and a plurality of insulation layers formed between the active layer and the metal layers are laminated on a substrate having a plurality of unit cell areas to form the array substrate. However, the array substrate may be transformed by stresses applied during the formation process of each of the layers. Therefore, a corrected pattern may not be formed on the transformed substrate during a subsequent process, or an arrangement defect may be generated when the array substrate is coupled with the color filter substrate.

### BRIEF SUMMARY OF THE INVENTION

The present invention provides an array substrate for a display device capable of preventing deformation of a substrate by decreasing stress that is generated during the formation of each layer of the array substrate.

The present invention also provides a method of manufacturing the above-mentioned array substrate.

In one embodiment of the present invention, an array substrate includes; a substrate, a thin-film transistor (“TFT”) formed on the substrate, the TFT including a plurality of metal patterns, and an insulation layer electrically insulated form the plurality of metal patterns, the insulation layer being spaced apart from at least one edge of the substrate by a predetermined distance.

In one embodiment, the insulation layer may be spaced apart from at least one side of the substrate by a predetermined width and the insulation layer is disposed on an inner portion of the substrate.

In another embodiment of the present invention, an array substrate includes; a TFT formed on a substrate, the TFT including an active pattern, a gate metal pattern and a data metal pattern, a first insulation layer insulating the active pattern from the gate metal pattern, and a second insulation layer spaced apart from at least one edge of the substrate by a predetermined distance, the second insulation layer insulating the gate metal pattern from the data metal pattern.

In one embodiment the second insulation layer is spaced apart from at least one side of the substrate by a predetermined width, and the insulation layer is disposed on an inner portion of the substrate.

In one embodiment, the substrate may have a substantially rectangular shape, and the second insulation layer may be spaced apart from a perimeter of the substrate by a predetermined width.

In one embodiment, the first and second insulation layers may be patterned to have plan shapes substantially identical to each other.

In still another embodiment of the present invention, an array substrate includes; a substrate including a display area and a peripheral area substantially surrounding the display area, an active pattern disposed on the substrate, a first insulation layer disposed on the substrate and covering the active pattern, a gate metal pattern disposed on the first insulation layer, a second insulation layer disposed on the first insulation layer and covering the active pattern and the gate metal pattern, the second insulation layer being spaced apart from at least one side of the substrate by a predetermined distance, and the second insulation layer being disposed on the substrate, a data metal pattern disposed on the second insulation layer, the data metal pattern being electrically connected to a portion of the active pattern through a contact hole disposed in the first and second insulation layer, and a pixel electrode electrically connected to at least one portion of the data metal pattern.

In one embodiment, the substrate may have a substantially rectangular shape, and the second insulation layer may be spaced apart from a perimeter of the substrate by a predetermined width.

In one embodiment, the first and second insulation layers may be patterned to have plan shapes substantially identical to each other.

In one embodiment, the active pattern may include a pixel pattern part disposed on the peripheral area, the pixel pattern part including a pixel high-density doped portion doped with first impurities at a relatively high concentration and a pixel low-density doped portion doped with first impurities at a relatively low concentration, a storage pattern part disposed on the peripheral area, the storage pattern part including a storage high-density doped portion doped with first impurities at a relatively high concentration and a storage low-density doped portion doped with first impurities at a relatively low concentration, and a driving pattern part disposed on the display area, the driving pattern part including a driving high-density doped portion doped with second impurities at a relatively low concentration, wherein the second insulation layer covers the pixel pattern part, the storage pattern part and the driving pattern part.

In one embodiment a method of manufacturing an array substrate includes; disposing a TFT including a plurality of metal patterns on a substrate, disposing an insulation layer insulating at least two of the plurality of metal patterns from each other, and spacing the insulation layer apart from at least one edge of the substrate by a predetermined distance.

In one embodiment, the forming the thin-film transistor includes; disposing an active pattern on the substrate, disposing a gate metal pattern on the active pattern, disposing a data metal pattern on the gate metal pattern, and disposing the insulation layer includes; disposing a first insulation layer on the gate metal pattern, the first insulation layer insulating the gate metal pattern from the data metal pattern, and removing a predetermined width of the first insulation layer along at least one edge of the substrate.

In one embodiment, a gate insulation layer which insulates the active pattern from the gate metal pattern may be disposed on the substrate.

In one embodiment of the present invention, there is provided a method of manufacturing an array substrate for a display device, the method including; disposing a polycrystalline pattern on a unit cell area of a mother substrate, wherein the unit cell area is defined by a cutting line, disposing a first insulation layer on the polycrystalline pattern, disposing a gate metal pattern on the first insulation layer, injecting impurities into the polycrystalline pattern on the unit cell area to form a source area and a drain area, disposing a second insulation layer on the gate metal pattern, removing a predetermined width of the second insulation layer along the cutting line, disposing a source electrode and a drain electrode in contact with the source and drain areas, respectively, disposing a third insulation layer on the source and drain electrodes and the second insulation layer, wherein the third insulation layer includes a portion exposing the drain electrode, electrically connecting a pixel electrode to the drain electrode, and cutting the mother substrate along the cutting line.

In one embodiment, the mother substrate may include a plurality of the unit cell areas defined thereon.

In one embodiment, a plurality of contact holes may be formed in the first and second insulation layer, the plurality of contact holes including a first contact hole disposed above the source electrode and a second contact hole disposed above the drain electrode, wherein the forming of the plurality of contact holes may be simultaneously performed with the removing of the second insulation layer.

In one embodiment, the forming of the contact holes and the removing of the predetermined width of the second insulation layer may be performed by a dry etching process.

In one embodiment, the removing of the predetermined width of the second insulation layer includes removing the second insulation layer along a cutting line which defines each unit cell area, thereby forming each of the unit cell areas in an island shape.

In one embodiment, the forming of the polycrystalline pattern includes; disposing an amorphous silicon layer on a unit cell area of the mother substrate, crystallizing the amorphous silicon layer to form a polysilicon layer, and then patterning the polysilicon layer.

In one embodiment, a light-blocking layer may be formed on the mother substrate before disposing the polycrystalline pattern on the unit cell area of the mother substrate.

In one embodiment, the mother substrate may be annealed after the injecting of impurities into the polycrystalline pattern,

According to the present invention, a second insulation layer is formed so that stress that is inflicted on a substrate may be decreased, thereby preventing deformation during a manufacturing process of the substrate.

Furthermore, deformation of the substrate may be prevented without an additional process, so that manufacturing costs may be reduced.

### BRIEF DESCRIPTION OF THE DRAWINGS

The above and other advantages of the present invention will become readily apparent by reference to the following detailed description when considered in conjunction with the accompanying drawings wherein:

FIG. 1 is a top plan view schematically illustrating an embodiment of a substrate including a unit cell according to the present invention;

FIG. 2 is an enlarged view of region “A” in FIG. 1;

FIG. 3 is a cross-sectional view taken along lines I-I′, II-II′ and III-III′ in FIG. 2; and

FIGS. 4 to 26 are cross-sectional views illustrating an embodiment of a manufacturing process of an array substrate according to the present invention.

### DETAILED DESCRIPTION OF THE INVENTION

The invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

Hereinafter, the present invention will be described in detail with reference to the accompanying drawings.

### Embodiment

Array substrate

Hereinafter, the array substrate for the display device according to an embodiment of the present invention will be described in detail with reference to the accompanying drawings.

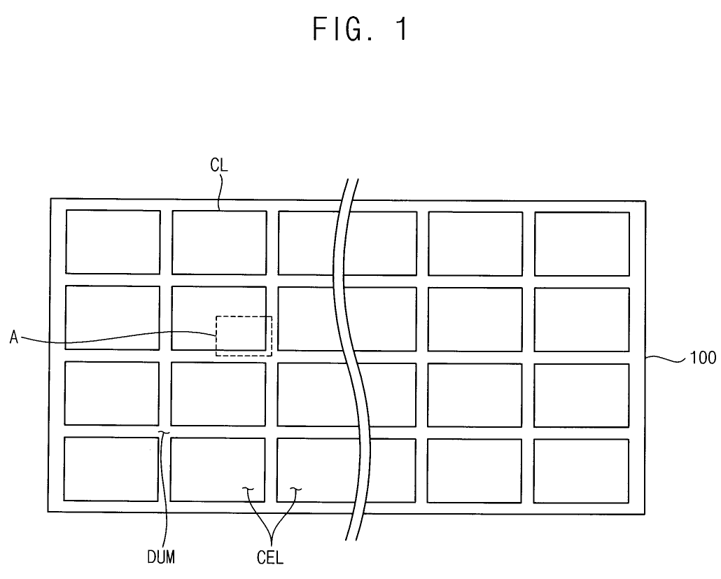

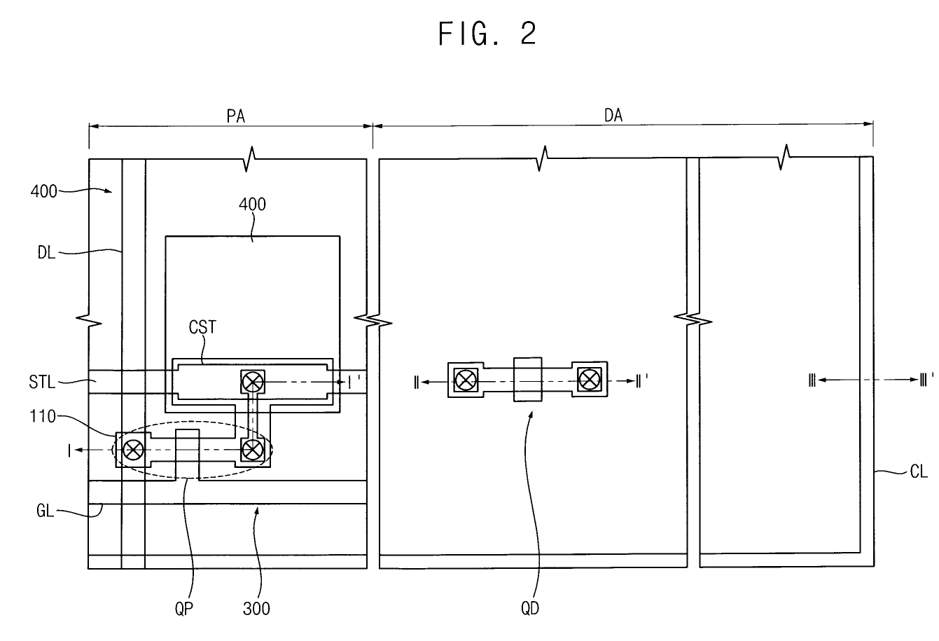

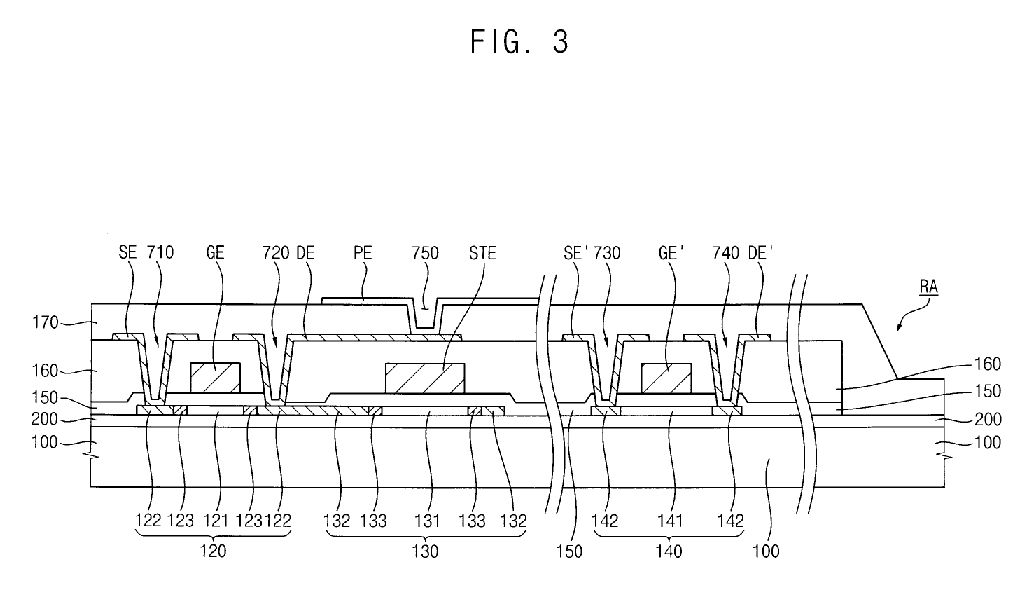

FIG. 1 is a top plan view schematically illustrating an embodiment of a substrate including a unit cell according to the present invention. FIG. 2 is an enlarged view of region “A” in FIG. 1. FIG. 3 is a cross-sectional view taken along lines I-I′, II-II′ and III-III′ of FIG. 2.

Firstly, an embodiment of an array substrate of the present invention is an element of a display panel. That is, an embodiment of a display panel may include an array substrate, a color filter substrate (not shown) facing the array substrate and a liquid crystal layer interposed between the array substrate and the color filter substrate. The array substrate is an element of the display panel.

As shown in FIG. 1, a mother substrate 100 including a display substrate (e.g., an array substrate) includes a unit cell CEL defined by a cutting line CL and a dummy area DUM which substantially surrounds the unit cell CEL. Here, at least one of the unit cells CEL may be defined in the mother substrate 100. For example, the mother substrate 100 may include a plurality of the unit cell areas CEL that are defined thereon as shown in FIG. 1.

According to an embodiment of the present invention, the mother substrate 100 may be cut along a cutting line CL, and then divided into the plurality of the unit cell areas CEL to form the array substrate. That is, each of the unit cell areas CEL defined on the mother substrate 100 may correspond to the array substrate.

Referring to FIGS. 2 and 3, a light blocking layer 200 is disposed on the substrate 100 and an active pattern 110, a first insulation layer 150, a gate metal pattern 300, a second insulation layer 160, a data metal pattern 400, a third insulation layer 170 and a pixel electrode PE are formed on the unit cell area CEL of the mother substrate 100, which, in the present embodiment, is defined by the cutting line CL.

The gate metal pattern 300 includes a plurality of gate lines GL, a plurality of storage lines STL and a plurality of gate electrodes GE and GE′. The gate lines GL are formed along a first direction. The storage lines STL are formed along the first direction in alternation with the gate lines GL. The storage lines STL may include storage capacitors CST. The data metal pattern 400 includes a plurality of data lines DL, a plurality of source electrodes SE and SE′, and a plurality of drain electrodes DE and DE′. The data lines DL are formed along a second direction crossing, and disposed substantially perpendicular to, the storage lines STL. In one embodiment, the gate lines GL and the data lines DL may define a plurality of pixel parts; however, the pixel parts may also be otherwise defined. The cell area CEL may include a display area DA corresponding to the pixel parts defined by the above and a peripheral area PA disposed substantially adjacent to the display area DA. In one embodiment the peripheral area PA is disposed substantially surrounding the display area DA.

In one embodiment, the mother substrate 100 includes an insulating substrate having a plate shape. In such an embodiment, the mother substrate 100 may include glass, quartz, synthetic resin, etc.

The activation pattern 110 is formed on the unit cell area CEL of the mother substrate 100. In an embodiment of the present invention, the activation pattern 110 includes polysilicon having excellent electrical conductivity. The activation pattern 110 includes a pixel pattern part 120, a storage pattern part 130 and a driving pattern part 140.

The pixel pattern part 120 is one of the elements of a pixel thin-film transistor (“TFT”) QP, and is formed in a peripheral area PA of the substrate 100. The pixel pattern part 120 includes a pixel channel portion 121, a pixel high-density doped portion 122 and a pixel low-density doped portion 123.

The pixel channel portion 121 includes polysilicon that has a relative lack of implanted impurities. The pixel high-density doped portion 122 is formed at two edges of the pixel channel portion 121. The pixel high-density doped portion 122 includes polysilicon which is doped with first impurities at a high concentration. The pixel low-density doped portion 123 is formed between the pixel channel portion 121 and the pixel high-density doped portion 122. The pixel low-density doped portion 123 includes polysilicon which is doped with the first impurities at a relatively low concentration. In one embodiment, the first impurities may include ions of a Group 15 element, embodiments of which include phosphorus (P).

In an embodiment of the present invention, the pixel channel portion 121 is formed in the peripheral area PA of the substrate 100; however, in an alternative embodiment the pixel pattern part 120 may include two pixel channel portions 121 spaced apart from each other, and the pixel low-density doped portion 123 and the pixel high-density doped portion 122 may be formed at end portions of each pixel channel portion 121.

The storage pattern part 130 is formed in the peripheral area PA of the substrate 100, and is extended from a portion of the pixel pattern part 120 as shown in FIG. 2. However, in an alternative embodiment, the storage pattern part 130 may be spaced apart from the pixel pattern part 120.

In one embodiment, the storage pattern part 130 includes a storage channel portion 131, a storage high-density doped portion 132 and a storage low-density doped portion 133.

The storage channel portion 131 includes polysilicon which has a relatively lack of implanted impurities. The storage high-density doped portion 132 is formed at two edges of the storage channel portion 131. The storage high-density doped portion 132 includes polysilicon which is doped with the first impurities at a relatively high concentration. The storage low-density doped portion 133 is formed between the storage channel portion 131 and the storage high-density doped portion 132. The storage low-density doped portion 133 includes polysilicon which is doped with the first impurities at a relatively low concentration. In one embodiment the first impurities may include ions of a Group 15 element, embodiments of which include phosphorus.

The driving pattern part 140 is one of the elements of a driving TFT QD, and is formed in a display area DA of the substrate 100. The driving pattern part 140 includes a driving channel portion 141 and a driving high-density doped portion 142.

The driving channel portion 141 includes polysilicon which has a relative lack of implanted impurities.

The driving high-density doped portion 142 is formed on two end potions of the driving channel portion 141. The driving high-density doped portion 142 may include polysilicon which has second impurities implanted at a relatively high concentration. Here, embodiments of second impurities may include ions of a Group 13 element, embodiments of which include boron.

In an embodiment of the present invention, the driving TFT QD includes the driving high-density doped portion 142 doped with ions of a Group 13 element. That is, the driving high-density doped portions 142 utilizing the second impurities including group 13 elements create a p-type metal-oxide semiconductor (“PMOS”). In an alternative embodiment, the driving TFT QD may include an n-type metal-oxide semiconductor (“NMOS”). That is, in an alternative embodiment the driving high-density doped portions 142 may utilize impurities including ions of a Group 15 element. In another alternative embodiment, the driving TFT QD may include a complementary metal-oxide semiconductor (“CMOS”) using the PMOS and the NMOS semiconductors. For example, when the driving TFT QD includes the CMOS, the power consumption of the LCD device may be increased.

The first insulation layer 150 is formed on the substrate 100 to substantially cover the active pattern 110. The first insulation layer 150 may include, for example, silicon nitride (“SiNx”), silicon oxide (“SiOx”), or other similar materials.

The gate metal pattern 300 is formed on the first insulation layer 150. The gate metal pattern 300 includes a gate line GL, a storage line STL, a storage electrode STE, a pixel gate electrode GE and a driving gate electrode GE.

The gate line GL is formed along a first direction, and the storage line STL is also formed along the first direction to be alternated with the gate line GL.

The pixel gate electrode GE is one of the elements of the pixel TFT QP. The pixel gate electrode GE protrudes from the gate line GL to be formed in alignment with the pixel channel portion 121. That is, the number of the pixel gate electrodes GE is substantially equal to that of the pixel channel portions 121.

The storage electrode STE is electrically connected to the storage line STL, and is formed in alignment with the storage high-density doped portion 131. Here, the storage electrode STE is overlapped with the storage high-density doped portion 131 by interposing the first insulation layer 150 therebetween to define a storage capacitor.

The driving gate electrode GE is one of the elements of the driving TFT QD. The driving gate electrode GE is formed in accordance with the driving channel portion 141 formed on the display area DA.

The second insulation layer 160 is formed on the first insulation layer 150 to cover the gate metal pattern 300. Embodiments of the second insulation layer 160 may include silicon nitride (“SiNx”), silicon oxide (“SiOx”), or other similar materials.

A first contact hole 710, a second contact hole 720, a third contact hole 730 and a fourth contact hole 740 are formed through the first and second insulation layers 150 and 160, respectively. The function of the first to fourth contact holes 710, 720, 730 and 740 will be described in detail in the following description of a data metal pattern 400.

The second insulation layer 160 is formed on the mother substrate 100. The second insulation layer 160 is spaced apart by a predetermined width from at least one edge of the mother substrate 100. For example, a portion of the second insulation layer 160 is removed by a predetermined width along a cutting line CL defining each unit cell area CEL of the mother substrate 100, so that the unit cell areas CEL may be formed on the mother substrate 100. In such an embodiment, the unit cell areas CEL have an island shape.

Accordingly, in view of each unit cell CEL, a predetermined width of the second insulation layer 160 is removed along an edge portion of the substrate 100 to define a removed area RA as shown in FIGS. 2 and 3. When a portion of the second insulation layer 160 formed on the mother substrate 100 is removed instead of forming the second insulation layer 160 on the whole area of the mother substrate 100, an amount of stress on the substrate 100 due to a deposition of the second insulation layer 160 may be reduced or effectively prevented. The second insulation layer 160 may stress the underlying substrate 100 due to their differing thermal coefficients; e.g., when heated the second insulation layer 160 may expand at a different rate than the underlying substrate, thereby creating shearing or flexing forces. Additionally, when a portion of the second insulation layer 160 is removed along a cutting line CL that defines the unit cell area CEL in accordance with an embodiment of the present invention, stress due to the second insulation layer 160 may be made more uniform in the mother substrate 100 so that deformation of the substrate 100 due to a deposition of the second insulation layer 160 may be reduced or effectively prevented.

In an alternative embodiment, the first insulation layer 150, which is disposed below the second insulation layer 160, may be removed during the removing the second insulation layer 160, so that the first and second insulation layers 150 and 160 may have substantially identical plan shapes.

The data metal pattern 400 is formed on the second insulation layer 160. The data metal pattern 400 includes a data line DL, a pixel source electrode SE, a pixel drain electrode DE, a driving source electrode SE and a driving drain electrode DE. Here, the pixel source electrode SE and the pixel drain electrode DE are elements of the pixel TFT QP, and are formed on the peripheral area PA. The driving source electrode SE and the driving drain electrode DE are elements of the driving TFT QD, and are formed on the display area DA.

The data line DL is formed along a direction crossing the gate line GL and the storage line STL. In one embodiment, a unit pixel may be formed between adjacent data lines DL and gate lines GL.

The pixel source electrode SE is formed to be overlapped with a portion of the pixel high-density doped portion 122. The pixel source electrode SE is electrically connected a portion of the pixel high-density doped portion 122 through the first contact hole 710 which exposes a portion of the pixel high-density doped portion 122.

The pixel drain electrode DE is spaced apart from the pixel source electrode SD by a predetermined distance. The pixel drain electrode DE is overlapped with another portion of the pixel high-density doped portion 122, and is electrically connected to another portion of the pixel high-density doped portion 122 through the second contact hole 720 which exposes another portion of the pixel high-density doped portion 122.

The driving source electrode SE′ is overlapped with a portion of the driving high-density doped portion 142. The driving source electrode SE is electrically connected to a portion of the driving high-density doped portion 142 through the third contact hole 730 which exposes a portion of the driving high-density doped portion 142.

The driving drain electrode DE is spaced apart from the driving source electrode SE by a predetermined distance. The driving drain electrode DE is overlapped with another portion of the driving high-density doped portion 142, and is electrically connected to another portion of the driving high-density doped portion 142 through the fourth contact hole 740 which exposes another portion of the driving high-density doped portion 142.

The third insulation layer 170 is formed on the second insulation layer 160 to cover the data metal pattern 400. Here, in one embodiment the third insulation layer 170 may be an organic insulation layer. Embodiments include configurations wherein a pixel contact hole 750 is formed through the third insulation layer 170, which exposes a portion of the pixel drain electrode DE.

The pixel electrode PE is formed on the third insulation layer 170, and is formed within each of the unit pixels. The pixel electrode PE is electrically connected to the pixel drain electrode DE through the pixel contact hole 750.

The pixel electrode PE includes an optically transparent and electrically conductive material. Embodiments of the pixel electrode PE may include, for example, indium tin oxide (“ITO”), indium zinc oxide (“IZO”), amorphous ITO (“a-ITO”), and other similar materials as would be apparent to one of ordinary skill in the art.

Method of Manufacturing an Array Substrate

Hereinafter, an embodiment of a method of manufacturing the embodiment of an array substrate illustrated in FIGS. 1 to 3 will be described in detail with reference to the accompanying drawings.

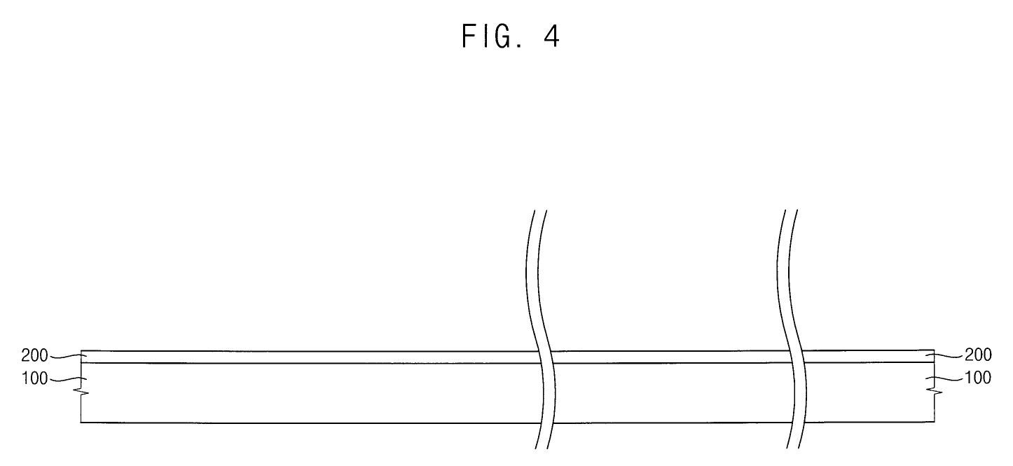

FIGS. 4 to 26 are cross-sectional views illustrating an embodiment of a manufacturing process of an embodiment of an array substrate according to the present invention.

Referring to FIG. 4, a light-blocking layer 200 is formed on a mother substrate 100. In one embodiment the light-blocking layer 200 is formed using a chemical vapor deposition (“CVD”) process. The process of forming the light-blocking layer 200 may be omitted. However, when the light-blocking layer 200 is formed on the mother substrate 100, energy required in crystal grain growth of a following active layer may be stored in the light-blocking layer 200. Furthermore, diffusion of alkali ions from the mother substrate 100 into the active layer may be prevented.

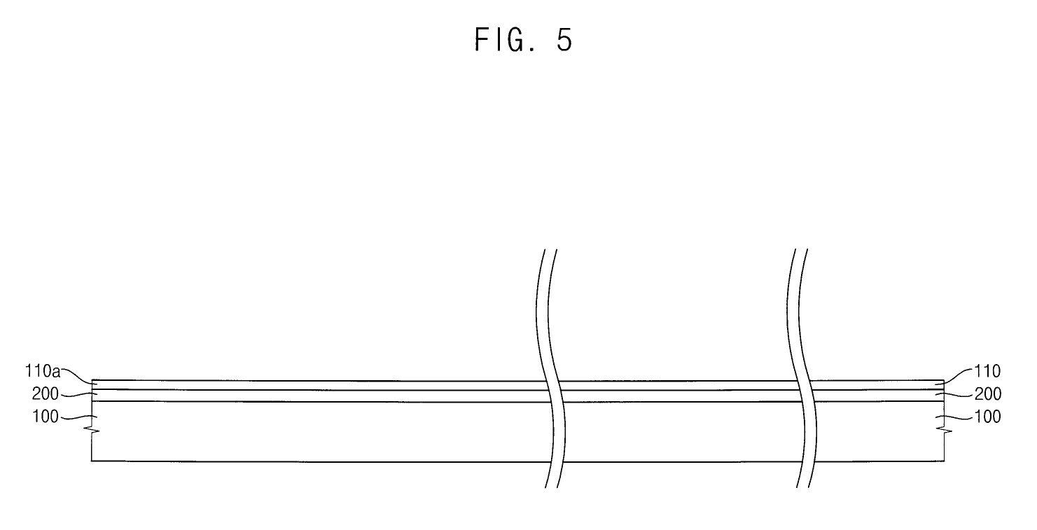

Then, as shown in FIG. 5, an amorphous silicon layer 110a with a thickness of about 500 Å to about 1,000 Å is formed on the mother substrate 100. In one embodiment the amorphous silicon layer 110a is formed using a CVD process. The CVD process for manufacturing the amorphous silicon layer 110a may include, for example, low-pressure CVD (“LPCVD”), plasma-enhanced CVD (“PECVD”), or other similar methods as would be apparent to one of ordinary skill in the art.

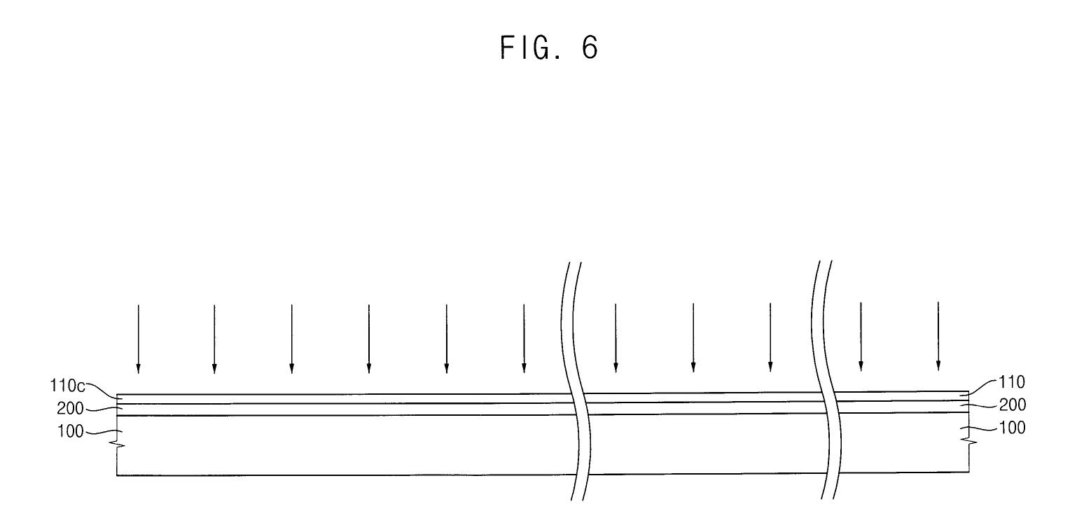

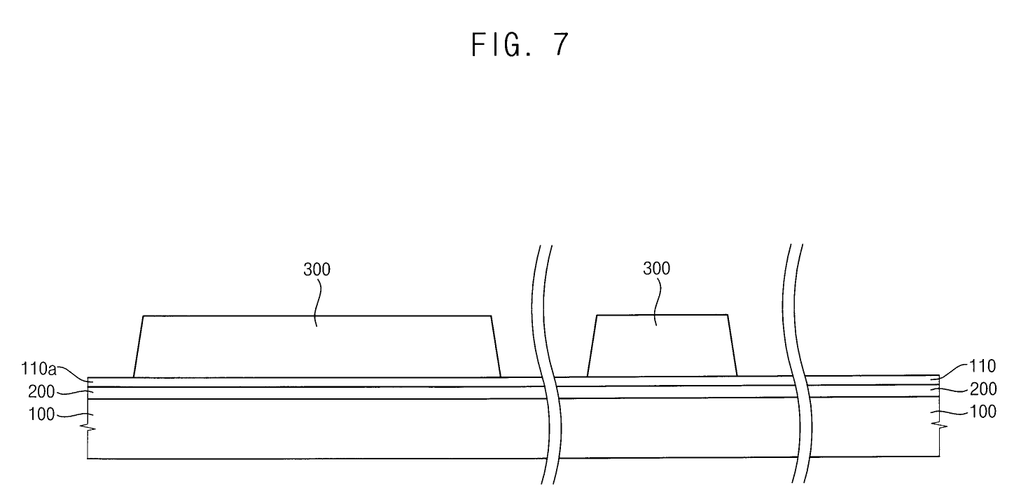

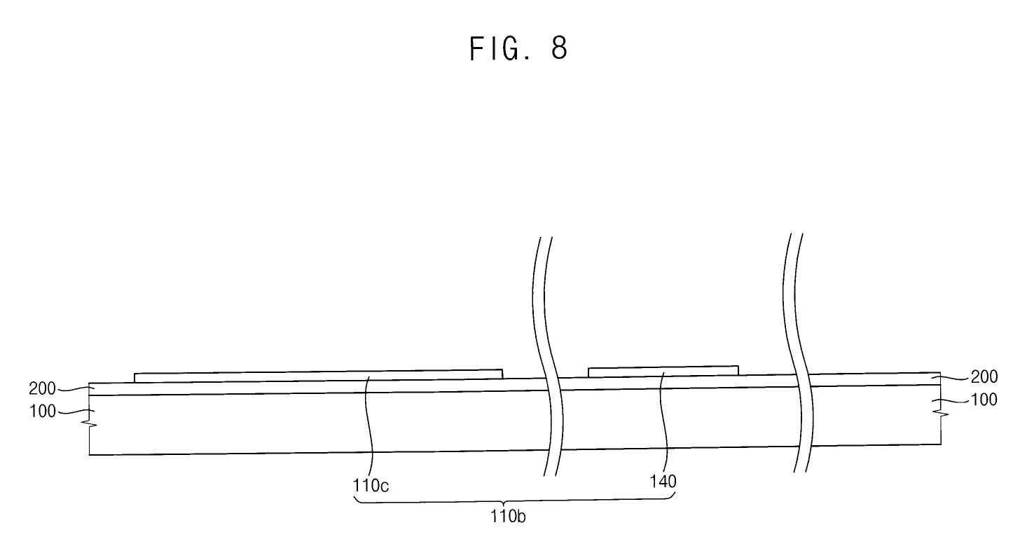

Then, as shown in FIGS. 6 to 8, the amorphous silicon layer 110a formed on the mother substrate 100 is crystallized to form a polysilicon layer (as shown in FIG. 6). Then, a photo-etching process using the photoresist layer 300 is performed to pattern the polysilicon pattern layer (as shown in FIG. 7), so that a polysilicon pattern 110b is formed on the mother substrate 100 (as shown in FIG. 8). Embodiments of the crystallization process include a high-energy laser beam irradiation of the deposited amorphous silicon layer 110a, so that the amorphous silicon may be crystallized.

The polycrystalline pattern 110b includes a first pattern part 110c and a second pattern part 140. The first pattern part 110c may be formed into a pixel pattern part and a storage pattern part which are formed on a peripheral area PA. The second pattern part 140 may be substantially identical to the driving pattern part 140 as shown in FIG. 3.

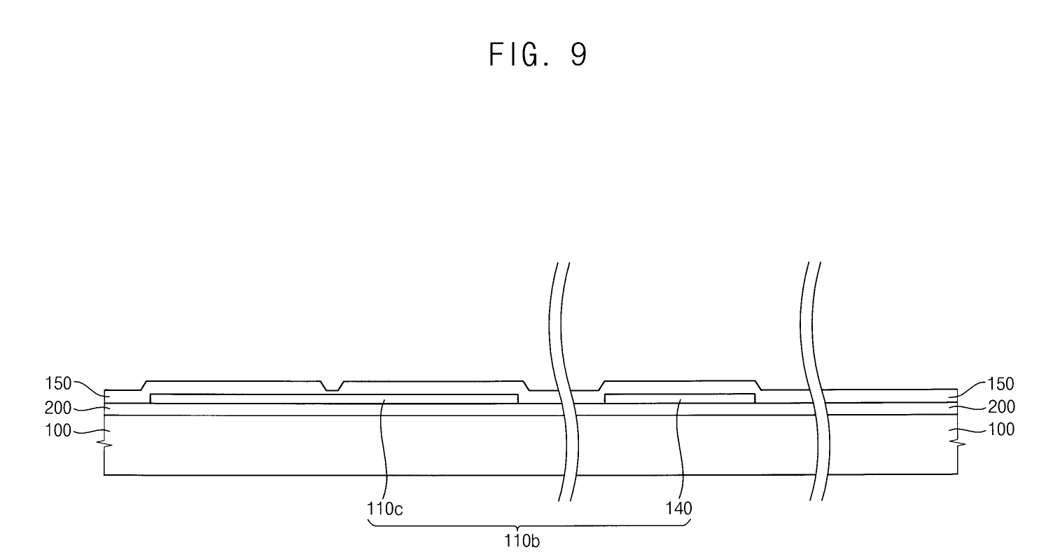

Then, as shown in FIG. 9, a first insulation layer 150 is formed to have a thickness of about 500 Å to 1,000 Å on the mother substrate 100 having the polycrystalline pattern 110b formed thereon. In one embodiment the first insulation layer 150 is formed by using PECVD. Embodiments of the first insulation layer 150 may include a single-layer structure or a double-layer structure. In one embodiment, when the first insulation layer 150 includes the single-layer structure, the first insulation layer 150 may include silicon oxide (“SiO2”). In another embodiment, when the first insulation layer 150 includes the double-layer structure, a lower layer of the first insulation layer 150 may include silicon oxide (“SiO2”) and an upper layer of the first insulation layer 150 may include silicon nitride (“SiNx”). Although the above embodiments discuss a single-layer structure and a double-layer structure, a multi-layer structure such as a triple-layer structure, a quadruple-layer structure or any other configuration known to one of ordinary skill in the art may also be utilized in place of or in conjunction with the single-layer structure.

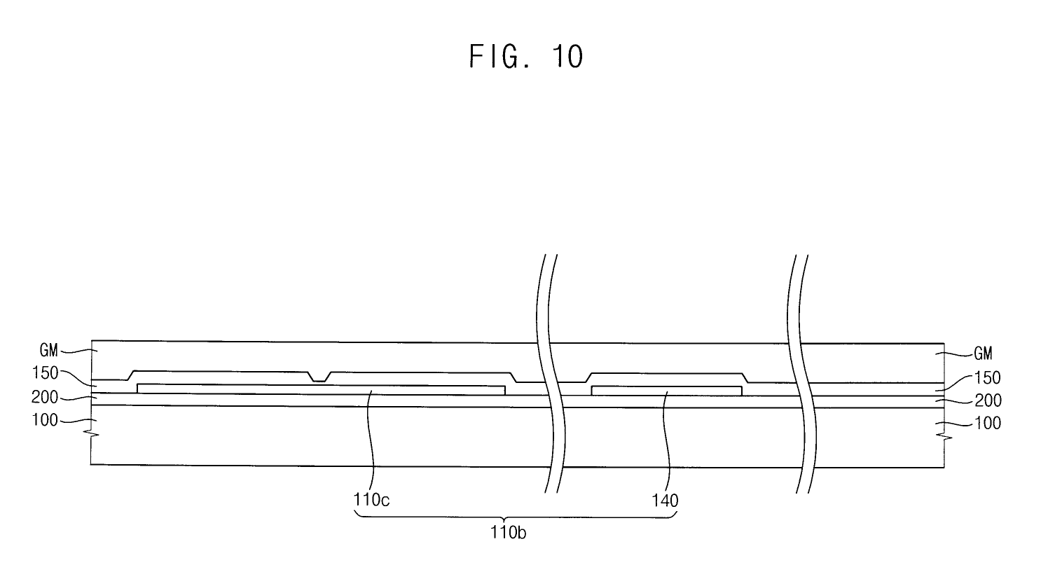

Then, as shown in FIG. 10, a first metal layer GM is formed to have a thickness of about 3,000 Å on the mother substrate 100 having the first insulation layer 150 formed thereon. In one embodiment the first metal layer GM is formed by using sputtering process. In one embodiment, the first metal layer GM includes an aluminum (Al) alloy, an aluminum-neodymium (“Al—Nd”) alloy, or other materials with similar characteristics.

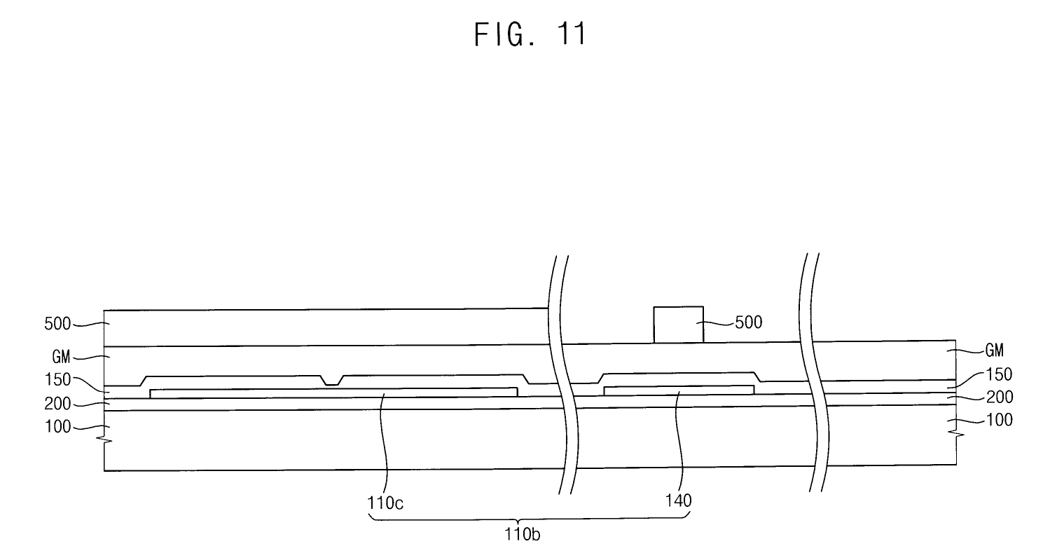

Then, as shown in FIG. 11, a first photosensitive layer (not shown) is formed on the mother substrate 100 having the first metal layer GM formed thereon. Then, the first photosensitive layer is patterned to form a first photosensitive pattern 500 by using a photolithographic process that uses a mask. In one embodiment, the first photosensitive layer may include a positive photoresist. In another embodiment, the first photosensitive layer may include a negative photoresist. In the embodiment wherein the first photosensitive layer includes a positive photoresist, a light-blocking pattern (not shown) is formed on the first mask in correspondence to an area for forming the first photosensitive pattern 500.

In one embodiment, openings in the first photosensitive pattern 500 are formed in alignment with an upper portion of the driving pattern part 140 to partially expose the first metal layer GM, and the first photosensitive pattern 500 is patterned to fully cover an upper portion of the first pattern part 110c which is to form the pixel pattern part and the storage pattern part.

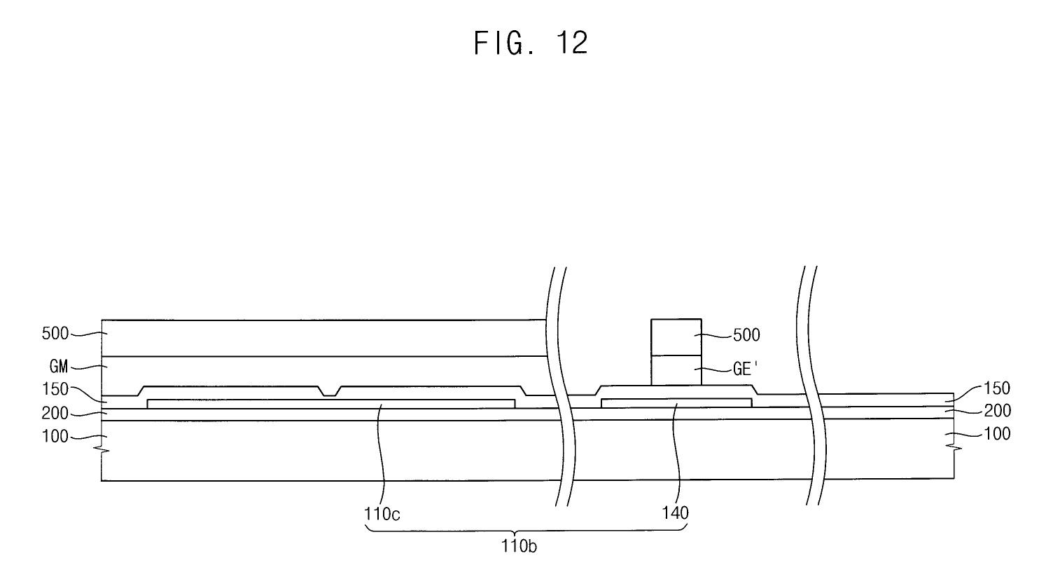

Then, as shown in FIG. 12, the first metal layer GM exposed by the opening of the first photosensitive pattern 500 is etched, and then the first photosensitive pattern 500 is removed to form the driving gate electrode GE′. Here, the driving gate electrode GE′ is patterned to cover a portion of the driving pattern part 140.

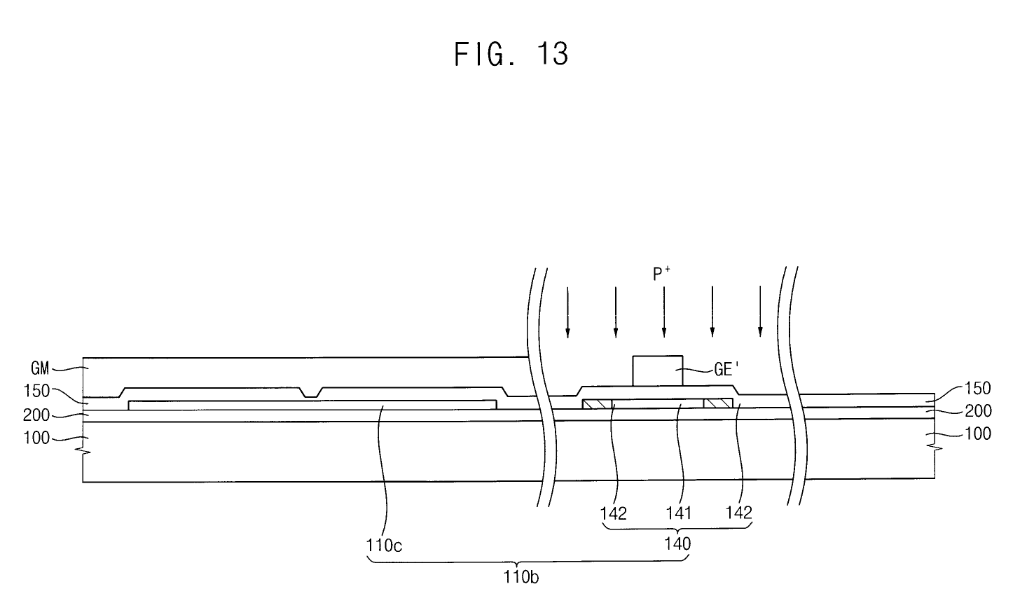

Then, as shown in FIG. 13, the driving pattern part 140 is doped with a high concentration of second impurities p+ to form a PMOS. Here, the second impurities p+ are not doped at a portion of the driving pattern part 140 that is covered with the driving gate electrode GE′, so that the area which is not doped with the second impurities p+ may be formed as the driving channel portion 141.

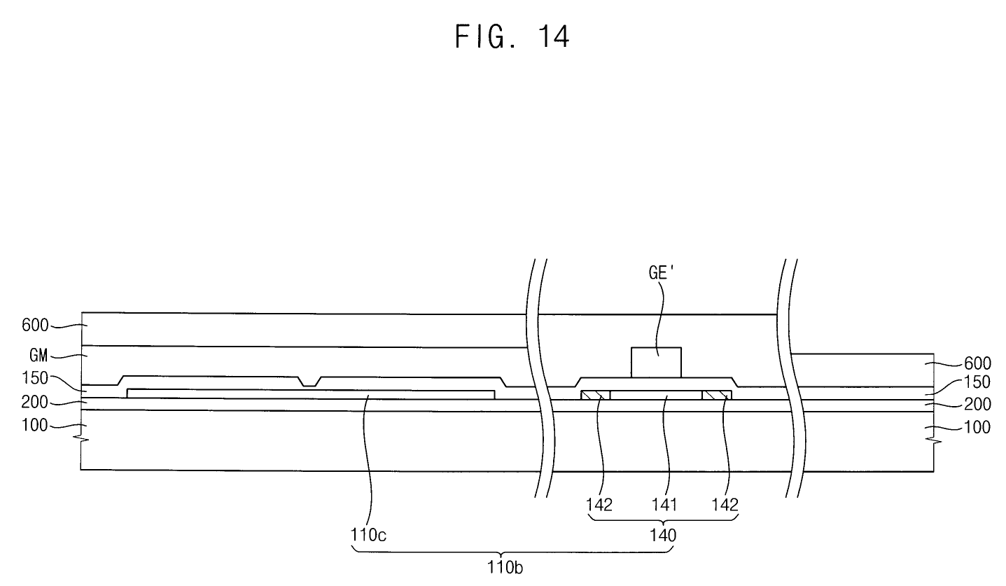

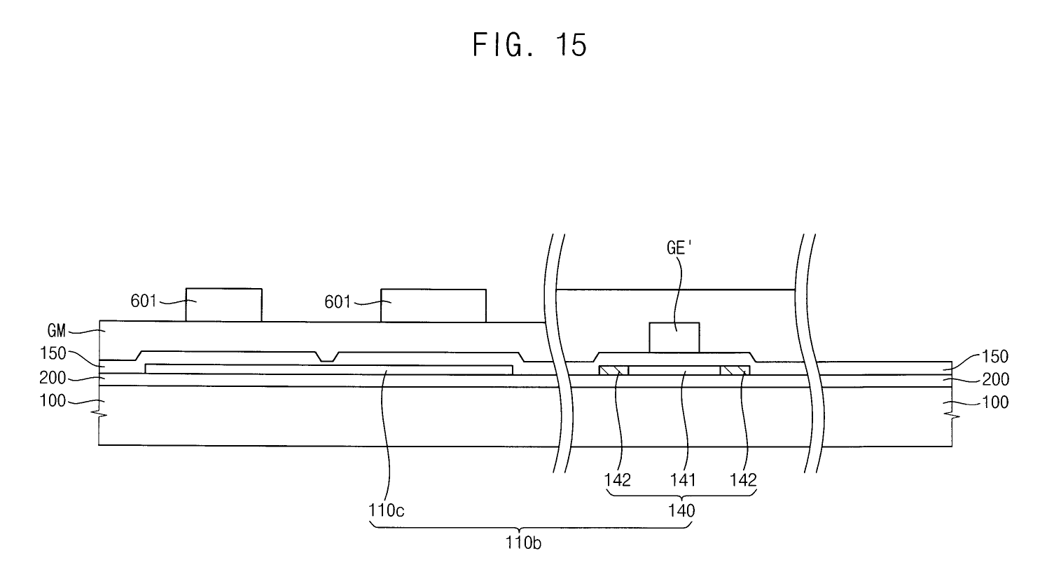

Then, as shown in FIGS. 14 and 15, a second photosensitive pattern 600 is formed. In one embodiment, the second photosensitive pattern 600 is transformed by a photo-etching process to create a second photosensitive layer 601 formed on the substrate 100.

For example, the second photosensitive pattern 600 is removed in a portion of the substrate 100 in alignment with an upper portion of the first pattern part 110c. The first pattern part 110c is to form the pixel pattern part and the storage pattern part. The second photosensitive pattern 600 is patterned to fully cover the driving pattern part 140.

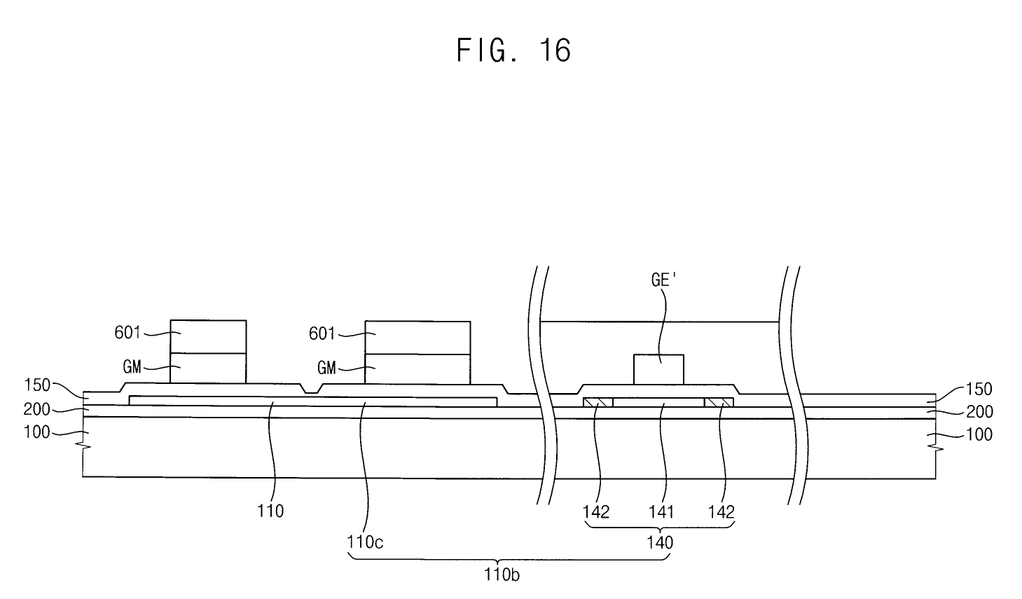

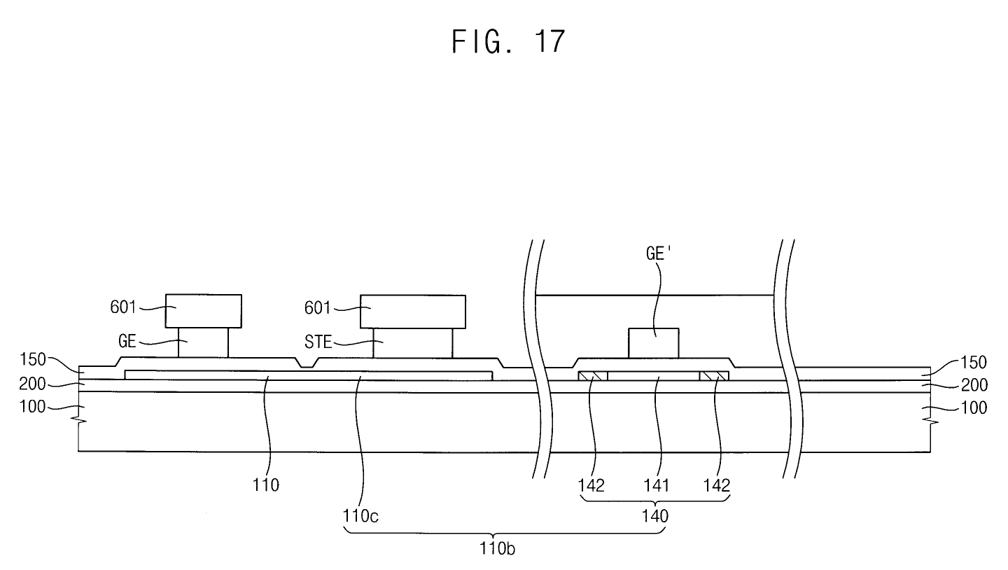

Then, as shown in FIGS. 16 and 17, the first metal layer GM is etched to form the pixel gate electrode GE and the storage electrode STE through an etching process. For example, the first metal layer GM exposed by the second photosensitive pattern 600 is dry-etched, so that the first metal layer GM is patterned to have a plan shape that is substantially identical to the second photosensitive pattern layer 601. Then, the first metal layer GM which remains after the dry-etching process is wet-etched to form the pixel gate electrode GE and the storage electrode STE. Here, an undercut of a predetermined width is formed in the pixel gate electrode GE and the storage electrode STE below the second photosensitive pattern 600 by the wet-etching process. The undercut may form a space for a doping of the first impurities at a low concentration, which is described below.

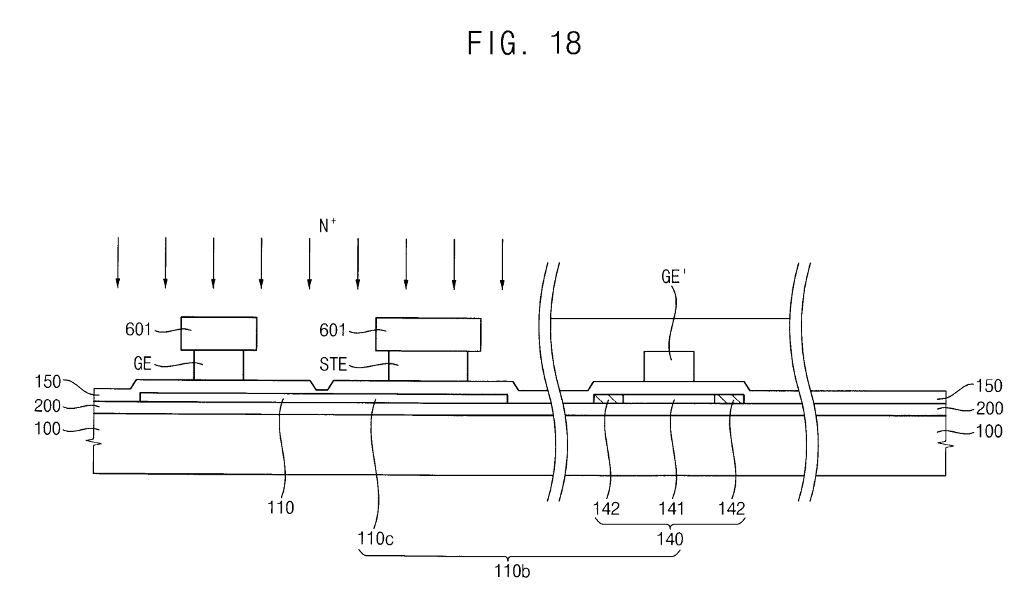

Then, as shown in FIGS. 18 to 21, first impurities of a high concentration are implanted into the first pattern part 110c using the second photosensitive pattern 600 as a mask. Then, the second photosensitive pattern 600 is removed to form a pixel pattern part 120 and the storage pattern part 130. In one embodiment the first impurities may include ions of a Group 15 element, embodiments of which include phosphorus (P).

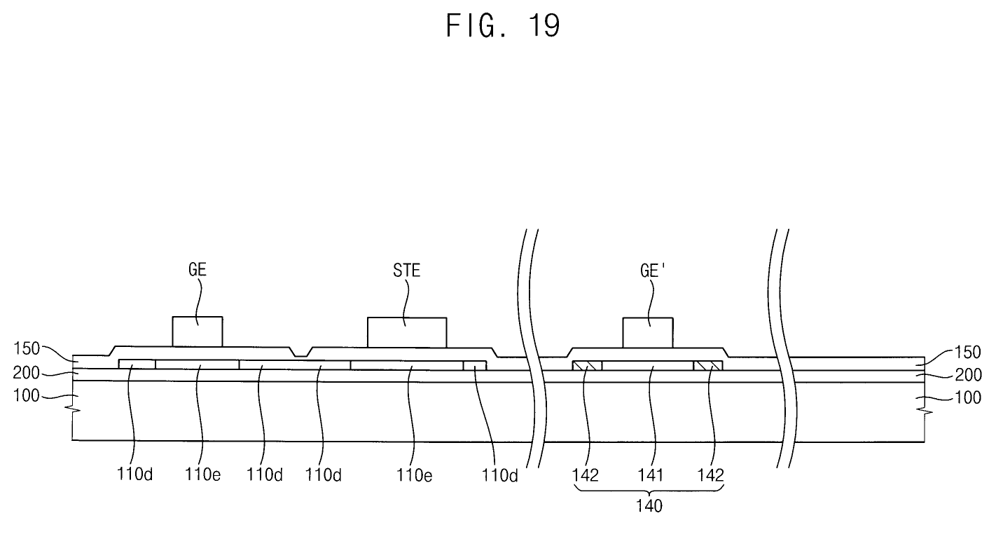

Referring to FIGS. 18 and 19, the first impurities are doped into a portion of the first pattern part 110c to form a doped portion 110d and an undoped portion 110e. Then, the second photosensitive pattern 600 is removed to expose the pixel gate electrode GE, the storage electrode STE and the driving gate electrode GE′. The formation of the pixel high-density doped portion 122 and the storage high-density doped portion 132 are completed by the high-density doping with the first impurities.

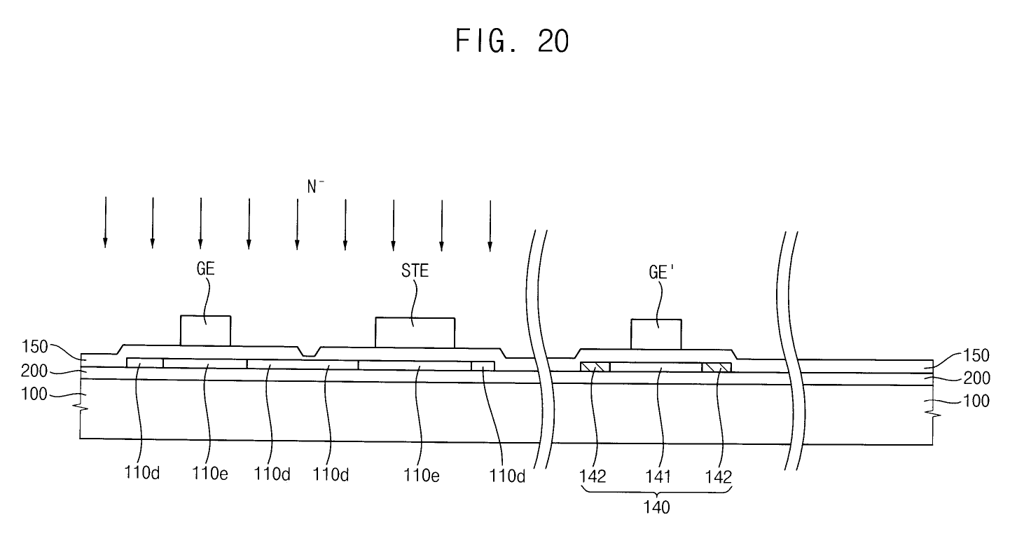

Then, as shown in FIG. 20, the first impurities n− of a low concentration are implanted into both the doped portion 110d and at least a portion of the undoped portion 110e not covered by an element of the gate metal layer such as the gate electrode GE or the storage electrode STE.

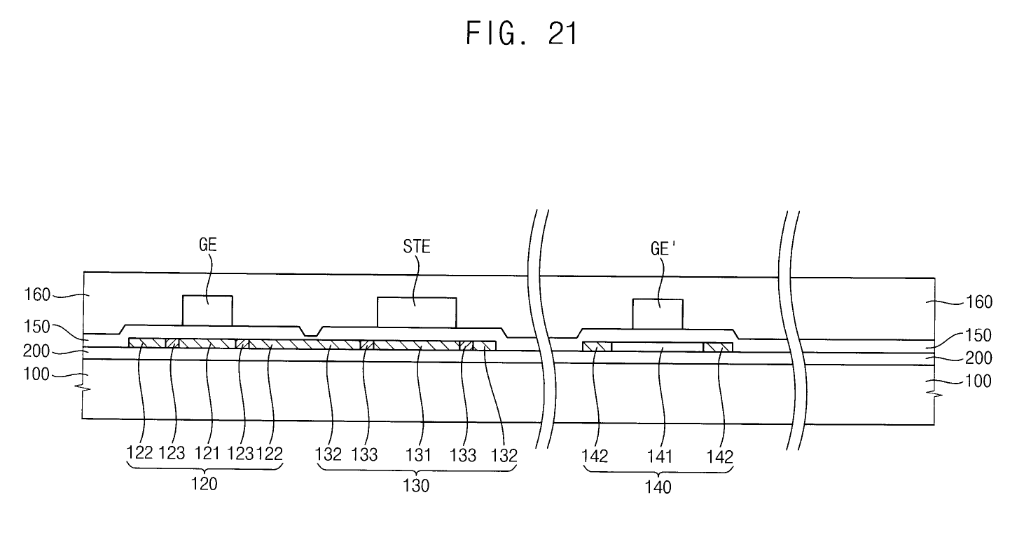

As a result, as shown in FIG. 21, a pixel low-density doped portion 123 and a pixel channel portion 121 are formed to define the pixel pattern part 120, and a storage low-density doped portion 133 and a storage channel portion 131 are formed to define the storage pattern part 130.

For example, when the first impurities n− of the low concentration are implanted into the doped portion 110d and the undoped portion 110e, the pixel gate electrode GE and the storage electrode STE function as masks, respectively. Therefore, the first impurities n− of the low concentration are not implanted in lower areas of the pixel gate electrode GE and the storage electrode STE, so that the pixel channel portion 121 is formed. Moreover, the first impurities n− of the low concentration do not affect the doped portion 110d, so that an implanted area implanted with the first impurities n− of the low concentration is limited to a lower portion of the undercut area of the pixel gate electrode GE and the storage electrode STE for the second photosensitive pattern 600 as shown in FIG. 18.

In an alternative embodiment, the mother substrate 100 may be annealed after the gate metal pattern is formed and the impurities are implanted, so that the implanted impurities may be activated. One embodiment of the annealing process of the mother substrate 100 may include rapid thermal annealing (“RTA”).

Then, as shown in FIG. 21, a second insulation layer 160 is formed on the mother substrate 100 to cover the gate metal pattern, that is the pixel gate electrode GE, the storage electrode STE and the driving gate electrode GE′.

In one embodiment, the second insulation layer 160 may include a double-layer structure. In the embodiment wherein second insulation layer 160 includes the double-layer structure, an embodiment of a lower layer of the second insulation layer 160 may be a silicon oxide (“SiO2”) layer having a thickness of about 4,500 Å, and an embodiment of an upper layer of the second insulation layer 160 may be a silicon nitride (“SiNx”) layer having a thickness of about 1,500 Å.

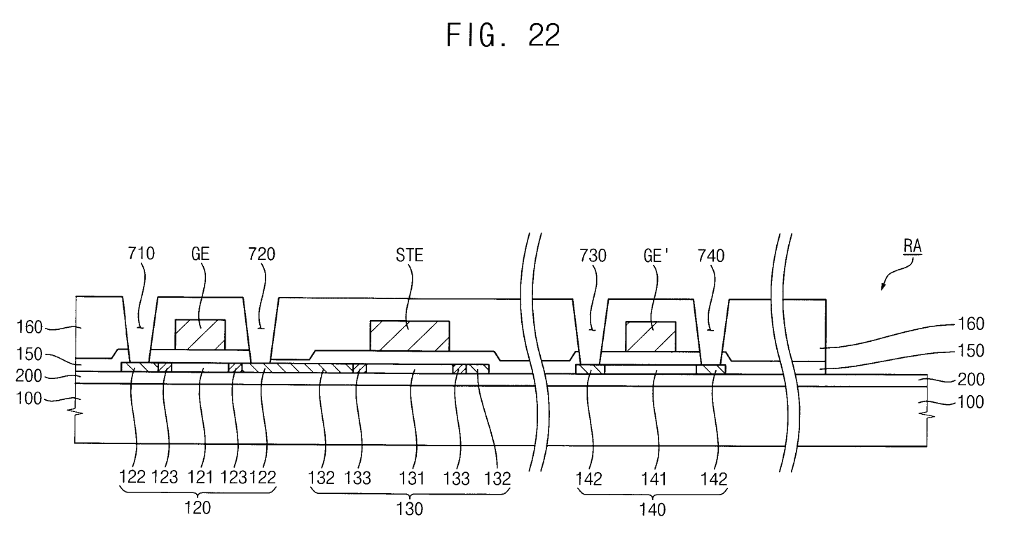

Then, as shown in FIG. 22, portions of the first and second insulation layer 150 and 160 are etched to form first, second, third and fourth contact holes 710, 720, 730 and 740. Here, the first contact hole 710 is formed through the first and second insulation layer 150 and 160 to a portion of the pixel high-density doped portion 122, and the second contact hole 720 is formed through the first and second insulation layer 150 and 160 to another portion of the pixel high-density doped portion 122. Moreover, the third contact hole 730 is formed though the first and second insulation layer 150 and 160 to a portion of the driving high-density doped portion 142, and the fourth contact hole 740 is formed through the first and second insulation layer 150 and 160 to another portion of the driving high-density doped portion 122.

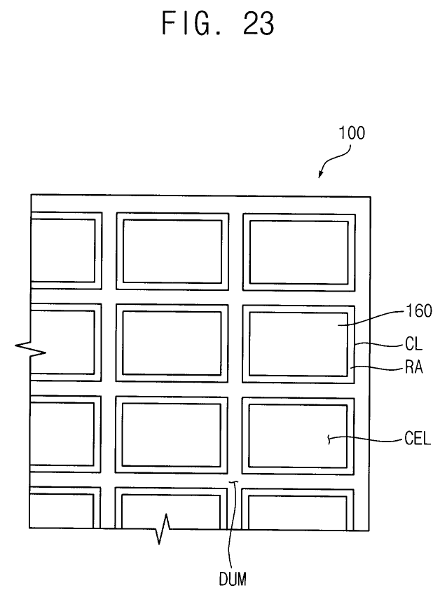

In an alternative embodiment, as shown in FIG. 23, in a formation process of the first to fourth contact holes 710, 720, 730 and 740, the second insulation layer 160 is etched by a predetermined width along a cutting line CL defining each unit cell area CEL of the mother substrate 100. Here, the removing area RA is defined along the cutting line CL, so that the second insulation layer 160 including the unit cell areas CEL, each of the unit cell areas CEL having an island shape, is formed on the mother substrate 100.

As described above, the second insulation layer 160, which is formed on portions of the mother substrate 100, is partially removed, so that an amount of stress due to the second insulation layer 160 may be decreased. Additionally, the removing area RA is formed by a predetermined width along the cutting line CL that defines the unit cell area CEL, so that stress due to the second insulation layer 160 may be uniformly distributed throughout the mother substrate 100. Therefore, deformation of the substrate 100 may be prevented. Furthermore, defects due to deformation of the mother substrate 100, for example, arrangement defects of a color filter substrate (not shown) and an array substrate may be reduced or effectively prevented.

Alternatively, the removing area RA is formed on the mother substrate 100 coincidently through the same process as that of the first to fourth contact holes 710, 720, 730 and 740. That is, the first to fourth contact holes 710, 720, 730 and 740 and the removing area RA may be coincidently formed through one etching process, so that deformation of the mother substrate 100 may be prevented without an additional process.

In one embodiment, the formation of the removing area RA and the first to fourth contact holes 710, 720, 730 and 740 may be performed by a wet etching process.

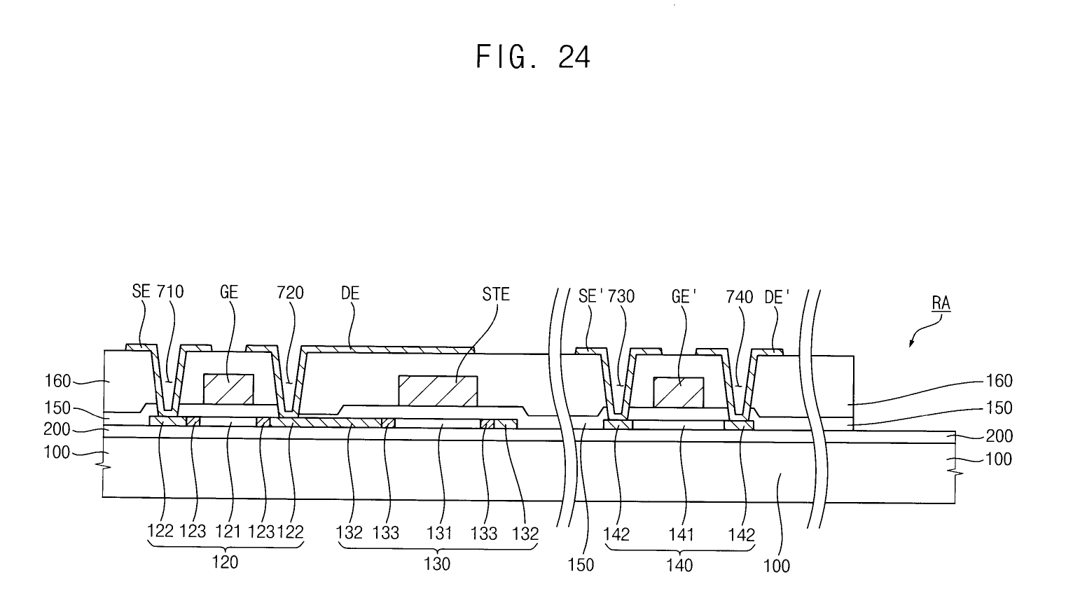

Then, as shown in FIG. 24, a data metal pattern 400 is formed on the second insulation layer 160, which is electrically connected to the pixel pattern part 120, the storage pattern part 130 and a portion of the driving pattern part 140 through the first to fourth contact holes 710, 720, 730 and 740. A data metal layer formed on the second insulation layer 160 is patterned to form the data metal pattern 400.

The data metal pattern 400 includes a data line DL, a pixel source electrode SE, a pixel drain electrode DE, a driving source electrode SE′ and a driving drain electrode DE′. Here, the pixel source electrode SE and the pixel drain electrode DE are elements of the pixel TFT QP, and are formed on the peripheral area PA. The driving source electrode SE′ and the driving drain electrode DE′ are elements of the driving TFT QD, and are formed on the display area DA (see FIG. 2).

The data line DL is formed along a direction substantially perpendicular to the gate line GL. The pixel source electrode SE is overlapped with a portion of the pixel high-density doped portion 122, and is electrically connected to a portion of the pixel high-density doped portion 122 through the first contact hole 710. The pixel drain electrode DE is spaced apart from the pixel source electrode SE by a predetermined distance to overlap another portion of the pixel high-density doped portion 122, and is electrically connected to another portion of the pixel high-density doped portion 122 through the second contact hole 720.

The driving source electrode SE′ is overlapped with a portion of the high-density doped portion 142 to be electrically connected to a portion of the driving high-density doped portion 142 through the third contact hole 730. The driving drain electrode DE′ is spaced apart from the driving source electrode SE′ by a predetermined distance to overlap another portion of the driving high-density doped portion 142, and is electrically connected to another portion of the driving high-density doped portion 142.

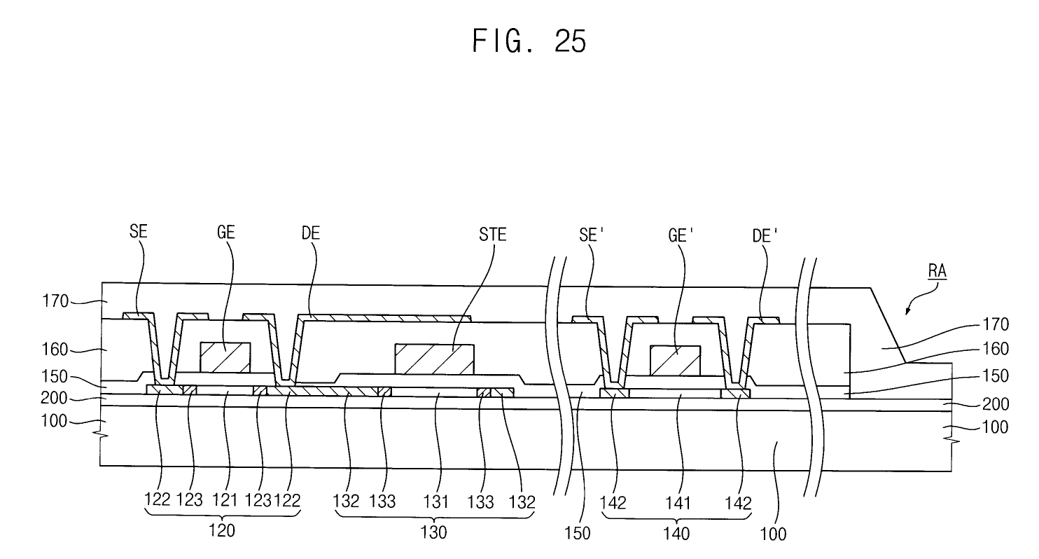

Then, as shown in FIG. 25, a third insulation layer 170 is formed on the second insulation layer 160 to cover the data metal pattern 400. The third insulation layer 170 is formed on the mother substrate 100 in the region wherein the second insulation layer 160 is spaced apart from at least one edge of the mother substrate 100. In one embodiment the third insulation layer 170 is thick enough that it may form an unbroken layer over the second insulation layer 160 in the removed area RA. In one embodiment the third insulation layer 170 may include an organic insulation layer.

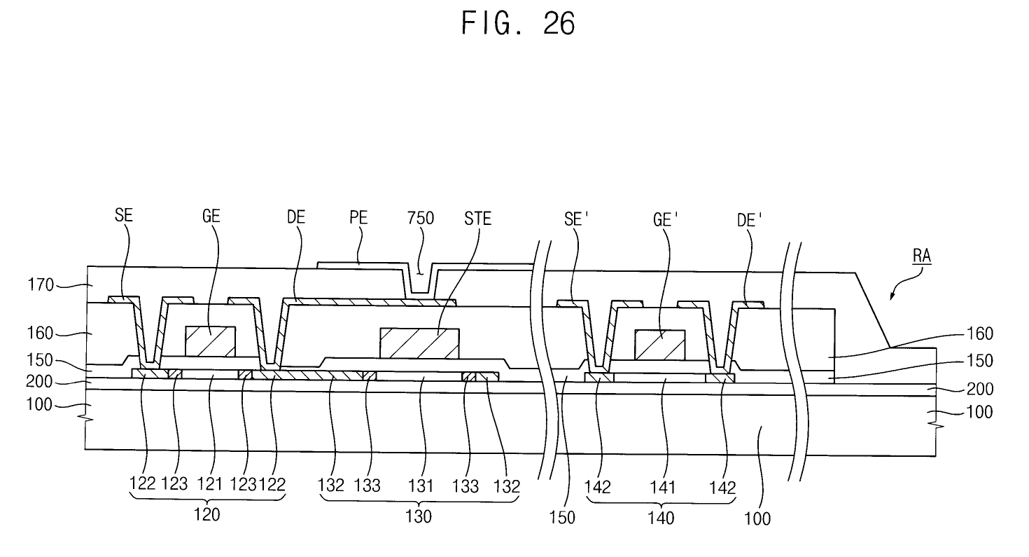

Then, as shown in FIG. 26, the pixel contact hole 750 is formed through the third insulation layer 170. The pixel contact hole 750 is formed through the third insulation layer 170 to reach the pixel drain electrode DE.

Finally, a pixel electrode PE is formed on the third insulation layer 170, which is electrically connected to the pixel drain electrode DE through the pixel contact hole 750. In one embodiment, a transparent metal layer may be formed on the third insulation layer 170 and then patterned to form the pixel electrode PE.

According to the present invention, a second insulation layer is formed so that stress that is inflicted on a substrate may be decreased, thereby preventing deformation during a manufacturing process of the substrate.

Furthermore, deformation of the substrate may be prevented without an additional process, so that manufacturing costs may be reduced.

Although the embodiments of the present invention have been described, it is understood that the present invention should not be limited to these embodiments but various changes and modifications can be made by one ordinary skilled in the art within the spirit and scope of the present invention as hereinafter claimed.

What is claimed is:

1. An array substrate comprising:
a substrate;
a thin-film transistor formed on the substrate, the thin-film transistor including a plurality of metal patterns; and
an insulation layer electrically insulated from the plurality of metal patterns, the insulation layer being spaced apart from at least one edge of the substrate by a predetermined distance.

2. The array substrate of claim 1, wherein the insulation layer is spaced apart from at least one side of the substrate by a predetermined width and the insulation layer is disposed on an inner portion of the substrate.

3. An array substrate comprising:
a thin-film transistor formed on a substrate, the thin film transistor including an active pattern, a gate metal pattern and a data metal pattern;
a first insulation layer insulating the active pattern from the gate metal pattern; and
a second insulation layer spaced apart from at least one edge of the substrate by a predetermined distance, the second insulation layer insulating the gate metal pattern from the data metal pattern.

4. The array substrate of claim 3, wherein the second insulation layer is spaced apart from at least one side of the substrate by a predetermined width, and the second insulation layer is disposed on an inner portion of the substrate.

5. The array substrate of claim 4, wherein the substrate has a substantially rectangular shape, and the second insulation layer is spaced apart from a perimeter of the substrate by a predetermined width.

6. The array substrate of claim 4, wherein the first insulation layer has a plan shape substantially identical to a plan shape of the second insulation layer.

7. An array substrate comprising:
a substrate including a display area and a peripheral area substantially surrounding the display area;
an active pattern disposed on the substrate;
a first insulation layer disposed on the substrate and covering the active pattern;
a gate metal pattern disposed on the first insulation layer;
a second insulation layer disposed on the first insulation layer and covering the active pattern and the gate metal pattern, the second insulation layer being spaced apart from at least one side of the substrate by a predetermined distance, and the second insulation layer being disposed on the substrate;
a data metal pattern disposed on the second insulation layer, the data metal pattern being electrically connected to a portion of the active pattern through a contact hole disposed in the first and second insulation layer; and
a pixel electrode electrically connected to at least one portion of the data metal pattern.

8. The array substrate of claim 7, wherein the substrate has a substantially rectangular shape, and the second insulation layer is spaced apart from a perimeter of the substrate by a predetermined width.

9. The array substrate of claim 7, wherein the first insulation layer has a plan shape substantially identical to a plan shape of the second insulation layer.

10. The array substrate of claim 7, wherein the active pattern comprises:
a pixel pattern part disposed on the peripheral area, the pixel pattern part including a pixel high-density doped portion doped with first impurities at a relatively high concentration and a pixel low-density doped portion doped with first impurities at a relatively low concentration;
a storage pattern part disposed on the peripheral area, the storage pattern part including a storage high-density doped portion doped with first impurities at a relatively high concentration and a storage low-density doped portion doped with first impurities at a relatively low concentration; and
a driving pattern part disposed on the display area, the driving pattern part including a driving high-density doped portion doped with second impurities at a relatively low concentration,
wherein the second insulation layer covers the pixel pattern part, the storage pattern part and the driving pattern part.

11. The array substrate of claim 10, wherein the substrate has a substantially rectangular shape, and the second insulation layer is spaced apart from a perimeter of the substrate by a predetermined width.

12. The array substrate of claim 10, wherein the first insulation layer has a plan shape substantially identical to the plan shape of the second insulation layer.

13. The array substrate of claim 7, further comprising a third insulation layer disposed on the second insulation layer and covering the data metal pattern, the third insulation layer having a contact hole disposed therein, wherein the pixel electrode electrically contacts at least one portion of the data metal pattern via the contact hole.

14. The array substrate of claim 13, wherein the third insulation layer is disposed on the substrate in the region wherein the second insulation layer is spaced apart from the at least one side of the substrate.

15. A method of manufacturing an array substrate, the method comprising:
disposing a thin-film transistor including a plurality of metal patterns on a substrate; and
disposing an insulation layer insulating at least two of the plurality of metal patterns from each other;
spacing the insulation layer apart from at least one edge of the substrate by a predetermined distance.

16. The method of claim 15, wherein forming the thin-film transistor comprises:
disposing an active pattern on the substrate;
disposing a gate metal pattern on the active pattern; and
disposing a data metal pattern on the gate metal pattern, and disposing the insulation layer comprises:
disposing a first insulation layer on the gate metal pattern, the first insulation layer insulating the gate metal pattern from the data metal pattern; and
removing a predetermined width of the first insulation layer along at least one edge of the substrate.

17. The method of claim 16, further comprising disposing a gate insulation layer, which insulates the active pattern from the gate metal pattern, on the substrate.

18. A method of manufacturing an array substrate for a display device, the method comprising:
disposing a polycrystalline pattern on a unit cell area of a mother substrate, wherein the unit cell area is defined by a cutting line;
disposing a first insulation layer on the polycrystalline pattern;
disposing a gate metal pattern on the first insulation layer;
injecting impurities into the polycrystalline pattern on the unit cell area to form a source area and a drain area;
disposing a second insulation layer on the gate metal pattern;
removing a predetermined width of the second insulation layer along the cutting line;
disposing a source electrode and a drain electrode in contact with the source and drain areas, respectively;
disposing a third insulation layer on the source and drain electrodes and the second insulation layer, wherein the third insulation layer includes a portion exposing the drain electrode;
electrically connecting a pixel electrode to the drain electrode; and
cutting the mother substrate along the cutting line.

19. The method of claim 18, wherein the mother substrate comprises a plurality of unit cell areas defined thereon.

20. The method of claim 18, further comprising forming a plurality of contact holes in the first and second insulation layers, the plurality of contact holes including a first contact hole disposed above the source electrode and a second contact hole disposed above the drain electrode,
wherein the forming of the plurality of contact holes is simultaneously performed with the removing of the predetermined width of the second insulation layer.

21. The method of claim 20, wherein forming the plurality of contact holes and the removing of the predetermined width of the second insulation layer are performed by a dry etching process.

22. The method of claim 20, wherein the removing of the predetermined width of the second insulation layer includes removing the second insulation layer along a cutting line which defines each unit cell area, thereby forming each of the unit cell areas in an island shape.

23. The method of claim 18, wherein forming the polycrystalline pattern comprises:
disposing an amorphous silicon layer on a unit cell area of the mother substrate;
crystallizing the amorphous silicon layer to form a polysilicon layer; and
patterning the polysilicon layer.

24. The method of claim 18, further comprising disposing a light-blocking layer on the mother substrate before disposing the polycrystalline pattern on the unit cell area of the mother substrate.

25. The method of claim 18, further comprising annealing the mother substrate after the injecting of impurities into the polycrystalline pattern.
